(19) United States
(12) Patent Application Publication
(10) Pub. No.: US 2013/0037944 A1
(43) Pub. Date: Feb. 14, 2013

(54) Chip Stack Packages Having Aligned Through Silicon Vias of Different Areas

(71) Applicants: Byung-Hyun Lee, Seongnam-si (KR); Hoon Lee, Seongnam-si (KR)

(72) Inventors: Byung-Hyun Lee, Seongnam-si (KR); Hoon Lee, Seongnam-si (KR)

(73) Assignee: Samsung Electronics Co., Ltd.

(21) Appl. No.: 13/568,367

(22) Filed: Aug. 7, 2012

(30) Foreign Application Priority Data
Aug. 9, 2011 (KR) 10-2011-0078949

(51) Int. Cl. H01L 23/488

(52) U.S. Cl. 257/737; 257/774; 257/E23.011; 257/E23.068

(57) ABSTRACT

A chip stack package includes a first semiconductor chip, a second semiconductor chip and a third semiconductor chip. The first semiconductor chip includes a first through silicon via that extends through the first semiconductor chip. The second semiconductor chip is stacked on the first semiconductor chip, and includes a second through silicon via that extends through the second semiconductor chip. The second through silicon via is disposed on the first through silicon via, and has a cross-sectional area smaller than that of the first through silicon via. The third semiconductor chip is stacked on the first semiconductor chip, and includes a third through silicon via that extends through the third semiconductor chip. The third through silicon via is disposed on the second through silicon via, and has a cross-sectional area smaller than that of the second through silicon via.

### CROSS-REFERENCE TO RELATED APPLICATIONS

This U.S. non-provisional application claims the benefit of priority under 35 U.S.C. §119 to Korean Patent Application No. 10-2011-0078949 filed on Aug. 9, 2011 in the Korean Intellectual Property Office (KIPO), the entire content of which is incorporated by reference herein in its entirety.

### BACKGROUND

Example embodiments relate to chip stack packages. More particularly, example embodiments relate to chip stack packages including a plurality of semiconductor chips each having a through silicon via.

A chip stack package is a package where a plurality of integrated circuit chips, such as semiconductor chips, is vertically stacked. To electrically connect the stacked semiconductor chips, a through silicon via (TSV) technique is used. The TSV technique is a three-dimensional package technique that electrically connects the stacked semiconductor chips by forming a small hole in each semiconductor chip and by filling the hole with a metal material. The TSV technique may obviate drawbacks, such as low speed, high power consumption, a large size, etc., of a conventional stack package using a metal wire. The term “through silicon via” is used for convenience as a recognized term of art. As used herein, TSV may be used in any integrated circuit chip, not just silicon-based chips.

### SUMMARY

Some example embodiments provide a chip stack package where a plurality of through silicon vias are efficiently and readily aligned and a capacitance of a signal path is efficiently and readily adjusted.

According to example embodiments, a chip stack package includes a first integrated circuit chip such as a semiconductor chip, a second semiconductor chip and a third semiconductor chip. The first semiconductor chip includes a first through silicon via that extends through the first semiconductor chip. The second semiconductor chip is stacked on the first semiconductor chip, and includes a second through silicon via that extends through the second semiconductor chip. The second through silicon via is disposed on the first through silicon via, and has a cross-sectional area smaller than that of the first through silicon via. The third semiconductor chip is stacked on the first semiconductor chip, and includes a third through silicon via that extends through the third semiconductor chip. The third through silicon via is disposed on the second through silicon via, and has a cross-sectional area smaller than that of the second through silicon via.

In some example embodiments, a capacitance of a signal path including the first to third through silicon vias is a function of the cross-sectional areas of the first to third through silicon vias.

In some example embodiments, the first to third through silicon vias may be aligned such that an entire lower surface of the second through silicon via is adjacent a surface of the first through silicon via and an entire lower surface of the third through silicon via overlaps an upper surface of the second through silicon via opposite or remote from the first through silicon via.

In some example embodiments, the chip stack package may further include a first metal pad adjacent the first through silicon via, a second metal pad on the first through silicon via, opposite or remote to the first metal pad, a third metal pad adjacent the second through silicon via, a fourth metal pad on the second through silicon via, opposite or remote to the third metal pad, a fifth metal pad adjacent the third through silicon via, a sixth metal pad on the third through silicon via, opposite or remote to the fifth metal pad, a first bump adjacent the first metal pad, opposite or remote to the first through silicon via, a second bump between the second metal pad and the third metal pad, and a third bump between the fourth metal pad and the fifth metal pad. The first semiconductor chip may be coupled to the second semiconductor chip through the second metal pad, the second bump and the third metal pad. The second semiconductor chip may be coupled to the third semiconductor chip through the fourth metal pad, the third bump and the fifth metal pad.

In some example embodiments, the first to third through silicon vias, the first though sixth metal pads and the first to third bumps may comprise at least one selected from the group consisting of copper (Cu), aluminum (Al), tin (Sn), nickel (Ni), gold (Au), tungsten (W), silicon (Si) and polysilicon.

In some example embodiments, the first semiconductor chip may further include a fourth through silicon via that extends through the first semiconductor chip, the second semiconductor chip may further include a fifth through silicon via that extends through the second semiconductor chip, and the third semiconductor chip may further include a sixth through silicon via that extends through the third semiconductor chip. The fourth through silicon via may have a cross-sectional area substantially the same as that of the first through silicon via, the fifth through silicon via may have a cross-sectional area substantially the same as that of the second through silicon via, and the sixth through silicon via may have a cross-sectional area substantially the same as that of the third through silicon via.

According to example embodiments, a chip stack package includes a plurality of semiconductor chips. The plurality of semiconductor chips include a plurality of through silicon vias respectively extending through the plurality of semiconductor chips. The plurality of semiconductor chips are stacked such that the plurality of through silicon vias may be aligned in a substantially straight line to form at least one signal path. The plurality of through silicon vias have different cross-sectional areas according to vertical positions of the plurality of semiconductor chips.

In some example embodiments, a capacitance of a signal path including the plurality of through silicon vias may be a function of the cross-sectional areas of the plurality of through silicon vias.

In some example embodiments, the chip stack package may further comprise a plurality of wiring layers, a respective one of which is on a respective one of the plurality of integrated circuit chips. The wiring layers may electrically connect one or more of the plurality of through silicon vias.

In some example embodiments, the plurality of semiconductor chips may be the same type of semiconductor chips performing the same function.

In some example embodiments, the plurality of semiconductor chips may be different types of semiconductor chips performing different functions.

In some example embodiments, the cross-sectional areas of the plurality of through silicon vias may gradually decrease in a direction from a lowermost one of the plurality of semiconductor chips to an uppermost one of the plurality of semiconductor chips.

In some example embodiments, the cross-sectional areas of the plurality of through silicon vias may gradually increase in a direction from a lowermost one of the plurality of semiconductor chips to an uppermost one of the plurality of semiconductor chips.

In some example embodiments, the cross-sectional areas of the plurality of through silicon vias may gradually decrease in a direction from a lowermost one of the plurality of semiconductor chips to an uppermost one of the plurality of semiconductor chips. The plurality of semiconductor chips may further include a plurality of respective through silicon vias having cross-sectional areas that gradually increase in the direction from the lowermost one of the plurality of semiconductor chips to the uppermost one of the plurality of semiconductor chips.

In some example embodiments, the cross-sectional area of each through silicon via may be in inverse proportion to a thickness of a corresponding one of the plurality of semiconductor chips.

In some example embodiments, capacitances of the plurality of through silicon vias may be the same as each other.

In some example embodiments, an integrated circuit chip stack package, may include a plurality of integrated circuit chip groups, where at least one of the integrated circuit chip groups includes a plurality of integrated circuit chips of a same type. These groups are stacked upon one another and the integrated circuit chips in a respective integrated circuit chip group are adjacent one another. The chips each includes at least one through silicon via extending through the integrated circuit chip. The chips of the at least one of the integrated circuit chip groups with a plurality of integrated circuit chips of a same type are stacked such that the plurality of through silicon vias are aligned to form at least one signal path.

In other example embodiments, the stack package with chip groups may include a plurality of wiring layers, a respective one of which is on a respective one of the plurality of integrated circuit chips where the wiring layers electrically connect one or more of the plurality of through silicon vias.

Other embodiments of the chip stack include where at least one of the integrated circuit chip groups may have a plurality of integrated circuit chips of a same type that have cross-sectional areas less than cross-sectional areas of the plurality of through silicon vias of the other integrated circuit chip groups.

In some example embodiments the cross-sectional areas of the through silicon vias of the one or more integrated circuit chips within at least one integrated circuit chip group change in a direction from a lowermost integrated circuit chip of the plurality of integrated circuit chips in the integrated circuit chip stack to an uppermost integrated circuit chip of the plurality of integrated circuit chips.

In other example embodiments, the cross-sectional areas of the plurality of the through silicon vias of the integrated circuit chips change in a direction from a lowermost integrated circuit chip in the integrated circuit chip stack to an uppermost integrated circuit chip in the integrated circuit chip stack.

As described above, in a chip stack package according to example embodiments, the plurality of through silicon vias may have different cross-sectional areas according to vertical positions of the plurality of semiconductor chips. Accordingly, the plurality of through silicon vias may be efficiently and readily aligned, and the entire capacitance of a signal path including the plurality of through silicon vias may be efficiently and readily adjusted.

### BRIEF DESCRIPTION OF THE DRAWINGS

Illustrative, non-limiting example embodiments will be more clearly understood from the following detailed description taken in conjunction with the accompanying drawings.

FIG. 1 is a cross-sectional view illustrating a chip stack package according to example embodiments.

FIG. 2 is a cross-sectional view illustrating a chip stack package according to example embodiments.

FIG. 3 is a cross-sectional view illustrating a chip stack package according to example embodiments.

FIG. 4A is a cross-sectional view illustrating a chip stack package according to example embodiments.

FIG. 4B is a cross-sectional view illustrating a chip stack package according to example embodiments.

FIG. 4C is a cross-sectional view illustrating a chip stack package according to example embodiments.

FIG. 5 is a cross-sectional view illustrating a chip stack package according to example embodiments.

FIG. 6 is a cross-sectional view illustrating a chip stack package according to example embodiments.

FIG. 7 is a cross-sectional view illustrating a chip stack package according to example embodiments.

FIGS. 8A to 8E are cross-sectional views for describing a method of forming a through silicon via according to example embodiments.

FIG. 9A is a diagram for describing an example of a wafer stack according to example embodiments.

FIG. 9B is a diagram for describing an example of a die stack according to example embodiments.

FIG. 10 is a block diagram illustrating a mobile system including a chip stack package according to example embodiments.

### DETAILED DESCRIPTION OF THE EMBODIMENTS

In a conventional chip stack package using TSVs, misalignment between TSVs that extend through adjacent semiconductor chips may occur since the TSV has such a small cross-sectional area. Various embodiments discussed herein may arise from recognizing that the misalignment between TSVs may tend to occur when different types of semiconductor chips are stacked. Further, a capacitance of a signal path including a plurality of TSVs may be increased if a plurality of semiconductor chips is stacked.

More specifically, a through silicon via (TSV) technique is a three-dimensional package technique that electrically connects a plurality of stacked semiconductor chips by forming a signal path that does not need a metal wire by using TSVs formed through the stacked semiconductor chips. The TSV technique may overcome drawbacks, such as low speed, high power consumption, a large size, etc., of a conventional stack package using a metal wire. However, in a conventional chip stack package using the TSV, since the TSV has such a small cross-sectional area, misalignment between TSVs formed through adjacent semiconductor chips may occur. In particular, the misalignment between TSVs may tend to occur when different types of semiconductor chips are stacked (e.g., when a processor chip and a memory chip are stacked). Furthermore, a capacitance of a signal path including a plurality of TSVs may be increased when a number of semiconductor chips are stacked.

In a chip stack package according to example embodiments, a plurality of TSVs may have different cross-sectional areas according to vertical positions of a plurality of semiconductor chips, which can efficiently and readily align the plurality of TSVs to form an electrically conductive signal path and can efficiently and readily adjust the entire capacitance of a signal path including the plurality of TSVs. For example, the cross-sectional areas of the TSVs may gradually decrease in a direction from the lowermost semiconductor chip to the uppermost semiconductor chip. In this case, the plurality of TSVs (or the semiconductor chips) may be aligned with a margin corresponding to a difference between the cross-sectional areas of adjacent TSVs. Thus, the plurality of TSVs may be efficiently and readily aligned in a line. Further, by using a characteristic that a capacitance of a TSV is in proportion to a cross-sectional area of the TSV, the capacitance of each TSV may be a function of the cross-sectional area of the TSV, and thus the entire capacitance of the signal path may be adjusted.

Various example embodiments will be described more fully hereinafter with reference to the accompanying drawings, in which some example embodiments are shown. The present inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

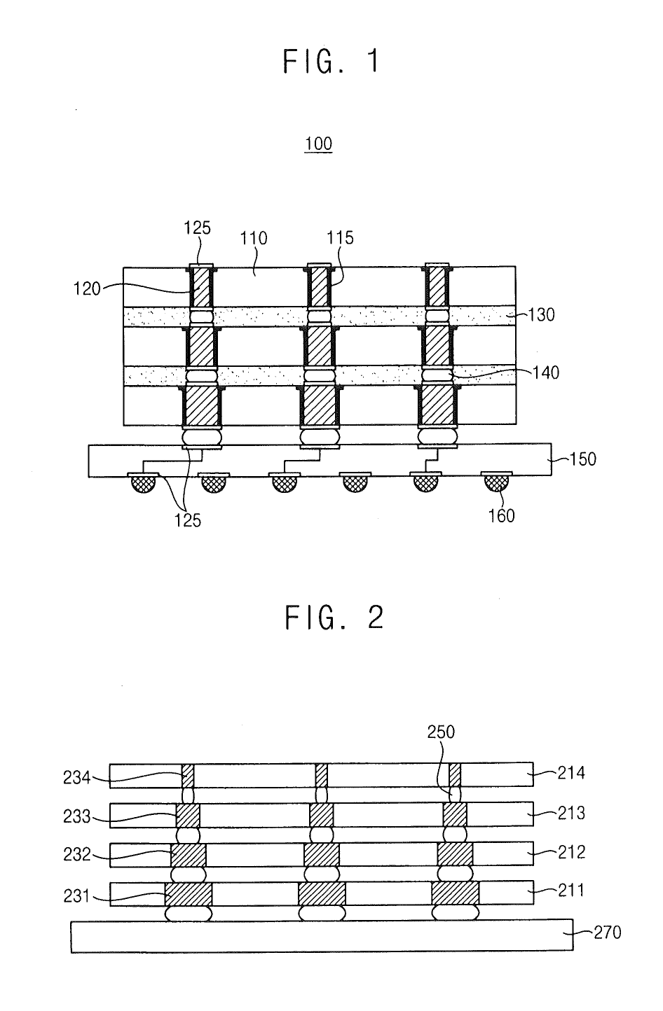

FIG. 1 is a cross-sectional view illustrating a chip stack package according to example embodiments.

Referring to FIG. 1, a chip stack package 100 includes a plurality of integrated circuit chips such as semiconductor chips 110, a plurality of through silicon vias (TSVs) 120, a plurality of metal pads 125, at least one insulation layer 130 between semiconductor chips, a plurality of bumps 140, a substrate 150 and at least one external-connection terminal 160. As illustrated in FIG. 1, the plurality of semiconductor chips 110 may be vertically stacked, and each through silicon via 120 may be extended through a corresponding one of the plurality of semiconductor chips 110 such that the plurality of through silicon vias 120 forms at least one signal path.

According to example embodiments, each semiconductor chip 110 may be a nonvolatile memory device, a volatile memory device, a processor (e.g., a central processing unit (CPU)), etc. In a case where the plurality of semiconductor chips 110 are a plurality of memory chips, the chip stack package 100 including the plurality of stacked memory chips may be a multi-memory chip. For example, a multi-memory chip of 8 GB may be formed by stacking eight 1 GB memory chips. The chip stack package 100 according to example embodiments may improve space efficiency by vertically stacking the plurality of semiconductor chips 110.

In some example embodiments, the plurality of semiconductor chips 110 may be the same type of semiconductor chips performing the same function. In other example embodiments, the plurality of semiconductor chips 110 may be different types of semiconductor chips performing different functions. For example, the chip stack package 100 may include a structure where a processor chip and a memory chip are vertically stacked. As will be described below, the plurality of through silicon vias 120 formed through the plurality of semiconductor chips 110 may have different cross-sectional areas according to vertical positions of the plurality of semiconductor chips 110, and thus the plurality of through silicon vias 120 may be accurately aligned in at least one substantially straight line.

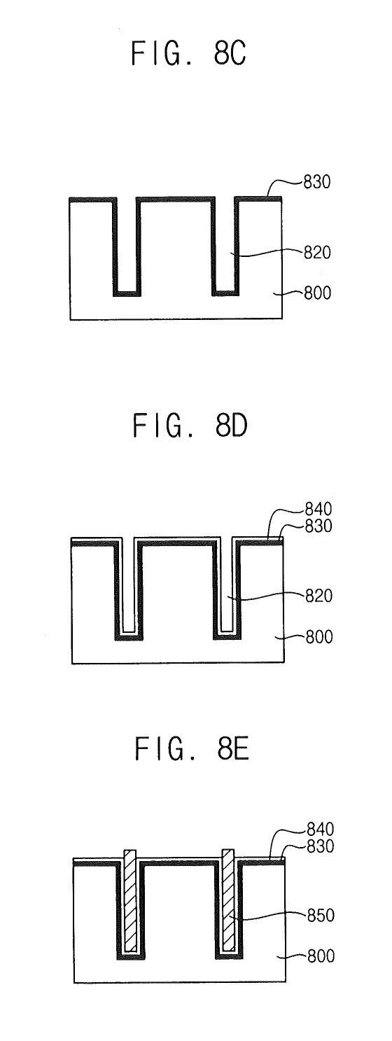

Each through silicon via 120 may be formed through a corresponding one of the plurality of semiconductor chips 110. A through silicon via (TSV) technique is a three-dimensional package technique that electrically connects stacked semiconductor chips by forming a small hole in each semiconductor chip and by filling the hole with a metal material. The TSV technique may obviate drawbacks, such as low speed, high power consumption, a large size, etc., of a conventional stack package using a metal wire. In some example embodiments, each through silicon via 120 may be formed such that a hole may be formed by etching the corresponding semiconductor chip 110 and the hole may be filled with a conductive material. Each through silicon via 120 may be surrounded with an insulating material 115. In some example embodiments, the insulating material 115 may include silicon dioxide (SiO2), tetraethyl orthosilicate (TEOS), etc. A method of forming the through silicon via 120 will be described below with reference to FIGS. 8A to 8E.

A metal pad 125 may be formed on an upper surface of each through silicon via 120, and another metal pad 125 may be formed beneath a lower surface of each through silicon via 120. Each metal pad 125 may include a conductive material, and may serve as an input/output terminal for electrically connecting the plurality of through silicon vias 120. A bump 140 may be inserted between on a lower metal pad 125 on an upper surface of a lower through silicon via 120 and an upper metal pad 125 beneath a lower surface of an upper through silicon via 120. Thus, the plurality of through silicon vias 120 that are aligned in a line may be electrically connected to each other through the plurality of metal pads 125 and the plurality of bumps 140. The bump 140 beneath the lowermost one of the plurality of semiconductor chips 110 may be electrically connected to the external-connection terminal 160 through the substrate 150. Thus, the plurality of semiconductor chips 110 may transmit/receive a signal from/to an external device through the external-connection terminal 160, the plurality of bumps 140, the plurality of metal pads 125 and the plurality of through silicon vias 120.

Each semiconductor chip 110 may include at least one through silicon via 120. For example, the number of through silicon vias 120 in each semiconductor chip 110 may be determined according to the number of terminals required by the semiconductor chip 110.

In some example embodiments, the plurality of through silicon vias 120, the plurality of metal pads 125 and the plurality of bumps 140 may be formed of the same conductive material. For example, the plurality of through silicon vias 120, the plurality of metal pads 125 and the plurality of bumps 140 may be formed of copper (Cu), aluminum (Al), tin (Sn), nickel (Ni), gold (Au), tungsten (W), silicon (Si), polysilicon, or an alloy thereof. A three-dimensional chip stack package using the TSV may be classified into a via first technique, a via middle technique and a via last technique. The via first technique may typically use a doped polysilicon as a filling material of the TSV to maintain thermal compatibility and compatibility of material with subsequent processes. The via middle technique and/or the via last technique may typically use tungsten or copper as the filling material of the TSV.

Since the plurality of bumps 140 disposed on the upper surfaces and/or the lower surfaces of the plurality of through silicon vias 120 protrude from the plurality of semiconductor chips 110, a space may exist between two adjacent semiconductor chips 110. The insulation layer 130 may be formed in this space, except in a region where a signal path (e.g., the bump 140) is formed. Accordingly, the chip stack package 100 may not include an empty space between the adjacent semiconductor chips 110. The insulation layer 130 may include an insulating material. For example, the insulation layer 130 may be formed as a non-conductive paste, a non-conductive film, etc. In some example embodiments, the insulation layer 130 may also serve as an adhesive layer to physically couple the plurality of semiconductor chips 110.

In some example embodiments, the plurality of through silicon vias 120 may have different cross-sectional areas according to vertical positions of the plurality of semiconductor chips 110, and the plurality of through silicon vias 120 formed through the same semiconductor chip 110 may have the same cross-sectional area. Since the plurality of through silicon vias 120 in one semiconductor chip are formed to have the same cross-sectional area, efficiency of a manufacturing process for the TSV may be improved.

In some example embodiments, the cross-sectional areas of the plurality of through silicon vias 120 may gradually decrease in a direction from the lowermost one of the plurality of semiconductor chips 110 to the uppermost one of the plurality of semiconductor chips 110. That is, the through silicon via 120 formed through the lowermost semiconductor chip 110 may have the largest cross-sectional area, and the through silicon via 120 formed through the uppermost semiconductor chip 110 may have the smallest cross-sectional area. For example, in a case where the plurality of semiconductor chips 110 include a first semiconductor chip, a second semiconductor chip stacked on the first semiconductor chip, and a third semiconductor chip stacked on the second semiconductor chip, and the plurality of through silicon vias 120 include a first through silicon via formed through the first semiconductor chip, a second through silicon via formed through the second semiconductor chip, and a third through silicon via formed through the third semiconductor chip, a cross-sectional area of the second through silicon via may be smaller than that of the first second through silicon via, and a cross-sectional area of the third through silicon via may be smaller than that of the second through silicon via. In this case, even if the stacked first to third semiconductor chips are not completely accurately aligned, the first to third silicon through vias may be accurately aligned such that an entire lower surface of the second through silicon via overlaps an upper surface of the first through silicon via and an entire lower surface of the third through silicon via overlaps an upper surface of the second through silicon via. That is, the second semiconductor chip may be stacked on the first semiconductor chip with a margin corresponding to a cross-sectional area difference between the first and second through silicon vias, and the third semiconductor chip may be stacked on the second semiconductor chip with a margin corresponding to a cross-sectional area difference between the second and third through silicon vias. As described above, the plurality of through silicon vias 120 formed through the plurality of semiconductor chips 110 may be efficiently aligned in a line by gradually decreasing the cross-sectional areas of the plurality of through silicon vias 120 according to vertical positions of the plurality of semiconductor chips 110, thereby preventing misalignment of the plurality of through silicon vias 120 having corresponding horizontal positions.

A typical through silicon via may have a cylinder shape, or the like, and may have a diameter of several μm or several tens μm. For example, the diameter of each typical through silicon via may be about 20 μm. Since each typical through silicon via has such a small cross-sectional area, misalignment between through silicon vias may occur when a plurality of conventional semiconductor chips are stacked. In particular, the misalignment between through silicon vias may tend to occur when different types of conventional semiconductor chips are stacked. In case of misalignment, the conventional semiconductor chips may be electrically disconnected from each other, and thus an entire system may not operate properly. However, in the chip stack package 100 according to example embodiments, the plurality of through silicon vias 120 may be formed such that the cross-sectional areas of the plurality of through silicon vias 120 gradually decrease according to vertical positions of the plurality of semiconductor chips 110, thereby efficiently and readily aligning the plurality of through silicon vias 120.

In some example embodiments, the entire capacitance of a signal path including the plurality of through silicon vias 120 may be a function of the cross-sectional areas of the plurality of through silicon vias 120. Hereinafter, a capacitance formed by the plurality of through silicon vias 120 will be described below.

Each through silicon via 120 may typically have a cylinder shape, and may include a conductive material, such as a metal. The through silicon via 120 including a conductive material may be formed through a semiconductor chip 110 including a conductive material, and the through silicon via 120 may be surrounded with the insulating material 115. That is, the insulating material 115 may be filled between the through silicon via 120 including the conductive material and the semiconductor chip 110 including the conductive material. Thus, the through silicon via 120, the insulating material 115 and the semiconductor chip 110 may form a cylinder-type capacitor. A capacitance of the through silicon via 120 may be calculated using a method of calculating a capacitance of a cylinder-type capacitor. For example, in a case where a radius of the through silicon via 120 is ‘r’ and a height of the through silicon via 120 is the capacitance of the through silicon via 120 may be calculated using Equation 1.

$$C = ɛ \times \frac{( L \times 2 π r )}{T} \qquad [ Equation 1 ]$$

Here, ε represents permittivity of the insulating material 115 between the through silicon via 120 and the semiconductor chip 110, and T represents a thickness of the insulating material 115. The capacitance may be in proportion to the radius of the through silicon via 120, or the cross-sectional area of the through silicon via 120. Thus, the capacitance of the through silicon via 120 may be adjusted by adjusting the cross-sectional area of the through silicon via 120. In the chip stack package 100 according to example embodiments, the plurality of through silicon vias 120 may be formed to have the cross-sectional areas that gradually decrease according to the vertical positions of the plurality of semiconductor chips 110, thereby not only efficiently and readily aligning the plurality of through silicon vias 120, but also reducing the entire capacitance of the signal path including the plurality of through silicon vias 120. Further, since the capacitance of the signal path is reduced, a signal of a high frequency may be accurately transferred even if multiple semiconductor chips 110 are stacked.

FIG. 2 is a cross-sectional view illustrating a chip stack package according to example embodiments. Components of the chip stack package, except a plurality of semiconductor chips 211, 212, 213 and 214, a plurality of through silicon vias 231, 232, 233 and 234, a plurality of bumps 250 and a substrate 270, are omitted from FIG. 2 for clarity of illustration.

Referring to FIG. 2, each semiconductor chip 211, 212, 213 and 214 includes at least one through silicon via 231, 232, 233 and 234. The number of through silicon vias 231, 232, 233 and 234 included in each semiconductor chip 211, 212, 213 and 214 may be determined according to the number of terminals required by the semiconductor chip 211, 212, 213 and 214. For example, as illustrated in FIG. 2, if a fourth semiconductor chip 214 requires three terminals, three through silicon vias 234 may be formed through the fourth semiconductor chip 214. In some example embodiments, a plurality of through silicon vias formed through one semiconductor chip may have the same cross-sectional area.

As illustrated in FIG. 2, first to fourth through silicon vias 231, 232, 233 and 234 respectively formed through first to fourth semiconductor chips 211, 212, 213 and 214 may have cross-sectional areas that gradually decrease in a direction from the lowermost semiconductor chip 211 to the uppermost semiconductor chip 214. Thus, an entire lower surface of the second through silicon via 232 may overlap an upper surface of the first through silicon via 231, an entire lower surface of the third through silicon via 233 may overlap an upper surface of the second through silicon via 232, and an entire lower surface of the fourth through silicon via 234 may overlaps an upper surface of the third through silicon via 233. Accordingly, the first to fourth through silicon vias 231, 232, 233 and 234 may be efficiently and readily aligned in a substantially straight line by forming the first to fourth through silicon vias 231, 232, 233 and 234 to have the cross-sectional areas that gradually decrease according to vertical positions of the semiconductor chips 211, 212, 213 and 214. Further, the entire capacitance of a signal path including the first to fourth through silicon vias 231, 232, 233 and 234 may be adjusted by adjusting the cross-sectional areas of the first to fourth through silicon vias 231, 232, 233 and 234. If the first to fourth through silicon vias 231, 232, 233 and 234 may have the cross-sectional areas that gradually decrease as illustrated in FIG. 2, the entire capacitance of the signal path may be reduced, and a signal of a high frequency may be accurately transferred even if multiple semiconductor chips 211, 212, 213 and 214 are stacked. The bump 250 and the substrate 270 may be substantially the same as a bump 140 and a substrate 150 illustrated in FIG. 1, and thus detailed descriptions for the bump 250 and the substrate 270 are omitted.

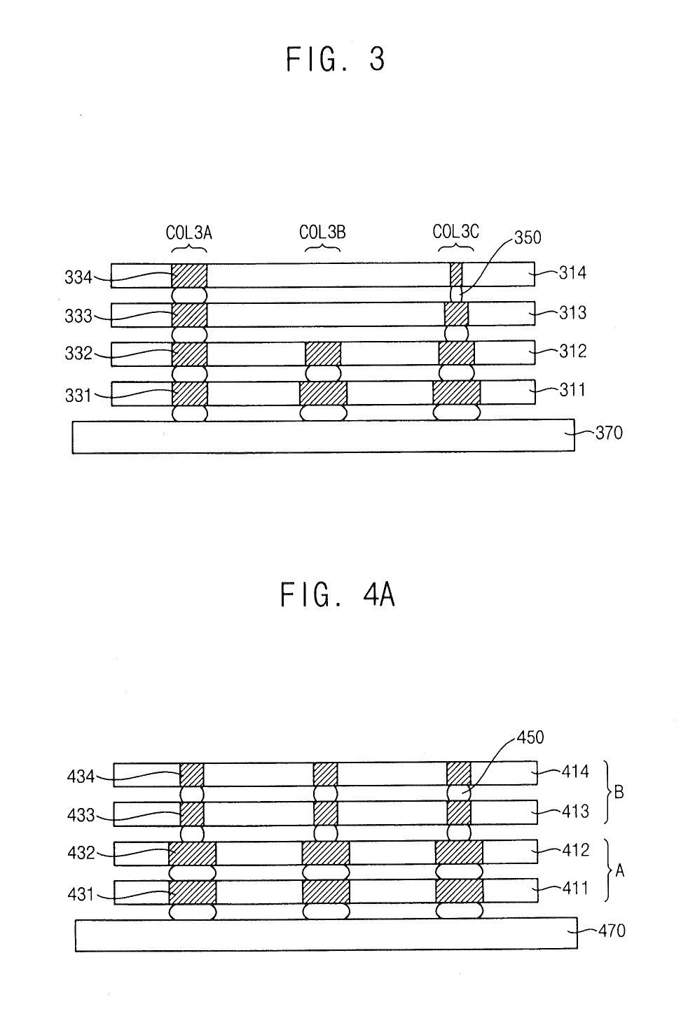

FIG. 3 is a cross-sectional view illustrating a chip stack package according to example embodiments. Components of the chip stack package, except a plurality of semiconductor chips 311, 312, 313 and 314, a plurality of through silicon vias 331, 332, 333 and 334, a plurality of bumps 350 and a substrate 370, are omitted in FIG. 3 for clarity of illustration.

Referring to FIG. 3, each semiconductor chip 311, 312, 313 and 314 includes at least one through silicon via 331, 332, 333 and 334. The number of through silicon vias 331, 332, 333 and 334 included in each semiconductor chip 311, 312, 313 and 314 may be determined according to the number of terminals required by the semiconductor chip 311, 312, 313 and 314. For example, as illustrated in FIG. 3, if a fourth semiconductor chip 314 requires two terminals, two through silicon vias 334 may be formed through the fourth semiconductor chip 314.

As illustrated in FIG. 3, a chip stack package may include at least one signal path COL3A, COL3B and COL3C including a plurality of through silicon vias 331, 332, 333 and 334. Each signal path COL3A, COL3B and COL3C may have one of various forms. For example, a first signal path COL3A may have substantially the same cross-sectional area in all semiconductor chips 311, 312, 313 and 314. The second signal path COL3B may be formed in a first semiconductor chip 311 and a second semiconductor chip 312, and may have a cross-sectional area that decreases according to vertical positions of the first and second semiconductor chips 311 and 312. The third signal path COL3C may have a cross-sectional area that increases according to vertical positions of the first to fourth semiconductor chips 311, 312, 313 and 314. As described above, the respective signal paths COL3A, COL3B and COL3C may have various forms. For example, the forms of the respective signal paths COL3A, COL3B and COL3C (or cross-sectional areas of the plurality of through silicon vias 331, 332, 333 and 334) may be determined according to characteristics of transmitted/received signals. The bump 350 and the substrate 370 may be substantially the same as a bump 140 and a substrate 150 illustrated in FIG. 1, and thus detailed descriptions for the bump 350 and the substrate 370 are omitted.

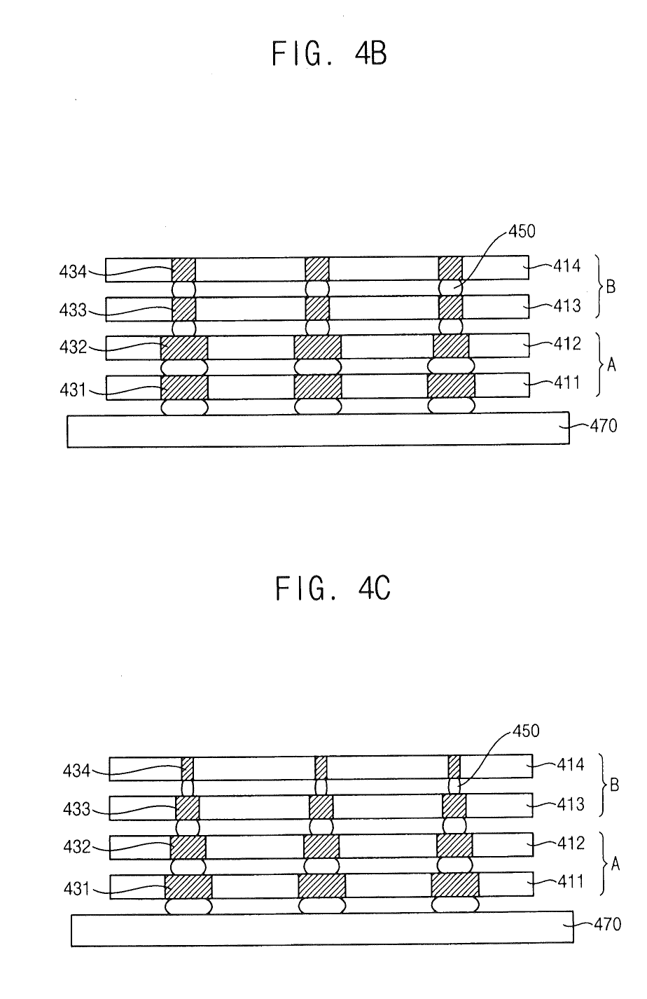

FIG. 4A is a cross-sectional view illustrating a chip stack package according to example embodiments. Components of the chip stack package, except a plurality of semiconductor chips 411, 412, 413 and 414, a plurality of through silicon vias 431, 432, 433 and 434, a plurality of bumps 450 and a substrate 470, are omitted in FIG. 4 for clarity of illustration.

Referring to FIG. 4A, each semiconductor chip 411, 412, 413 and 414 includes at least one through silicon via 431, 432, 433 and 434. The number of through silicon vias 431, 432, 433 and 434 included in each semiconductor chip 411, 412, 413 and 414 may be determined according to the number of terminals required by the semiconductor chip 411, 412, 413 and 414. For example, as illustrated in FIG. 4A, if a fourth semiconductor chip 414 requires four terminals, four through silicon vias 434 may be formed through the fourth semiconductor chip 414.

In some example embodiments, the chip stack package may include different types of semiconductor chips performing different functions. For example, the chip stack package may include a first semiconductor chip group A that includes first and second semiconductor chips 411 and 412 performing a first function and a second semiconductor chip group B that includes third and fourth semiconductor chips 413 and 414 performing a second function that is different from the first function. In some example embodiments, first and second through silicon vias 431 and 432 formed in the first semiconductor chip group A may have the same cross-sectional area as each other, and third and fourth through silicon vias 433 and 434 formed in the second semiconductor chip group B may have the same cross-sectional area as each other. Further, cross-section areas of the third and fourth through silicon vias 433 and 434 formed in the second semiconductor chip group B may be smaller than those of the first and second through silicon vias 431 and 432 formed in the first semiconductor chip group A. As described above, the cross-sectional areas of the plurality of through silicon vias 431, 432, 433 and 434 may vary according to the semiconductor chip groups A and B, thereby efficiently and readily aligning the plurality of through silicon vias 431, 432, 433 and 434 and efficiently and readily adjusting the entire capacitance of each signal path. The bump 450 and the substrate 470 may be substantially the same as a bump 140 and a substrate 150 illustrated in FIG. 1, and thus detailed descriptions for the bump 450 and the substrate 470 are omitted.

FIG. 4A illustrates an embodiment where the cross-sectional areas of the through silicon vias within a chip group are the same as one another. For example, the through silicon vias of the integrated circuit chips of chip group A are of a first cross-sectional area, while the through silicon vias of the integrated circuit chips of chip group B are of a second cross-sectional area. FIG. 4B illustrates an embodiment where the cross-sectional area decrease going up the chip stack within chip group A, while they may be constant in other chips groups. FIG. 4C illustrates an embodiment where the cross-sectional areas decrease going up the entire chip stack, irrespective of the group membership.

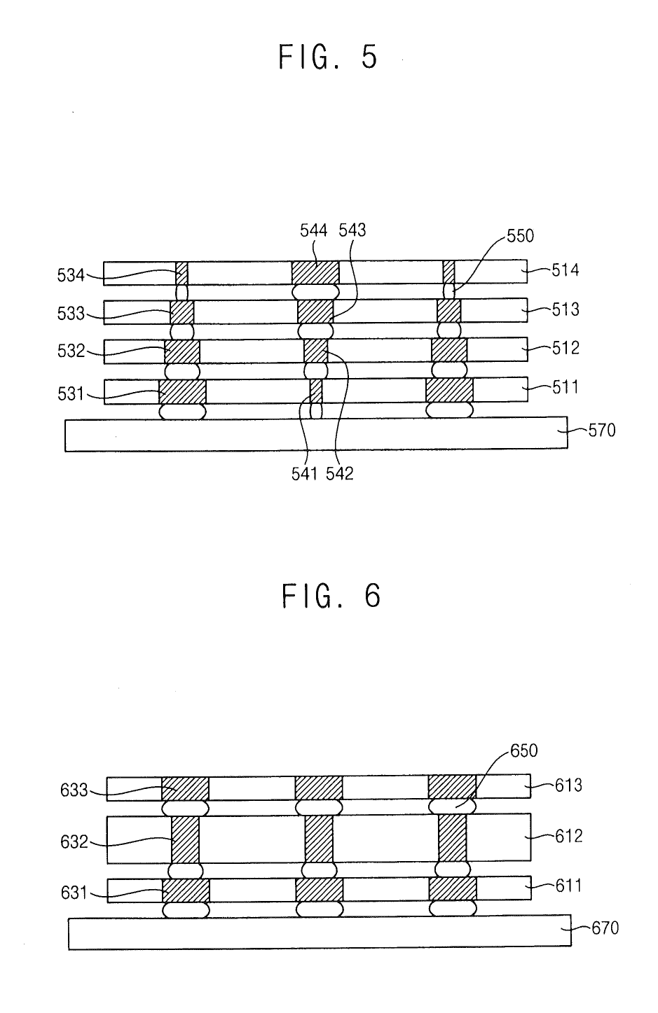

FIG. 5 is a cross-sectional view illustrating a chip stack package according to example embodiments. Components of the chip stack package, except a plurality of semiconductor chips 511, 512, 513 and 514, a plurality of through silicon vias 531, 532, 533, 534, 541, 542, 543 and 544, a plurality of bumps 550 and a substrate 570, are omitted from FIG. 5 for clarity of illustration.

Referring to FIG. 5, each semiconductor chip 511, 512, 513 and 514 includes at least one through silicon via 531, 532, 533, 534, 541, 542, 543 and 544. As illustrated in FIG. 5, each signal path included in the chip stack package may have one of various forms. For example, a first signal path including first through fourth through silicon vias 531, 532, 533 and 534 may have a cross-sectional area that gradually decreases according to vertical positions of the plurality of semiconductor chips 511, 512, 513 and 514, and a second signal path including fifth through eighth through silicon vias 541, 542, 543 and 544 may have a cross-sectional area that gradually increases according to the vertical positions of the plurality of semiconductor chips 511, 512, 513 and 514. As described above, cross-sectional areas of the plurality of through silicon vias 531, 532, 533, 534, 541, 542, 543 and 544 included in each signal path may vary according to the vertical positions of the plurality of semiconductor chips 511, 512, 513 and 514, thereby efficiently and readily aligning the plurality of through silicon vias 531, 532, 533, 534, 541, 542, 543 and 544 and efficiently and readily adjusting the entire capacitance of each signal path. The bump 550 and the substrate 570 may be substantially the same as a bump 140 and a substrate 150 illustrated in FIG. 1, and thus detailed descriptions for the bump 550 and the substrate 570 are omitted.

FIG. 6 is a cross-sectional view illustrating a chip stack package according to example embodiments. Components of the chip stack package, except a plurality of semiconductor chips 611, 612 and 613, a plurality of through silicon vias 631, 632 and 633, a plurality of bumps 650 and a substrate 670, are omitted in FIG. 6 for clarity of illustration.

Referring to FIG. 6, each semiconductor chip 611, 612 and 613 includes at least one through silicon via 631, 632 and 633. The number of through silicon vias 631, 632 and 633 included in each semiconductor chip 611, 612 and 613 may be determined according to the number of terminals required by the semiconductor chip 611, 612 and 613. For example, as illustrated in FIG. 6, if a third semiconductor chip 613 requires three terminals, three through silicon vias 633 may be formed through the third semiconductor chip 613.

In some example embodiments, a cross-sectional area of each through silicon via 631, 632 and 633 may be in inverse proportion to a thickness of a semiconductor chip 611, 612 and 613 through which the through silicon via 631, 632 and 633 is formed. As illustrated in FIG. 6, a second through silicon via 632 formed through a second semiconductor chip 612 that is relatively thick may have a cross-sectional area smaller than that of a first through silicon via 633 formed through a first semiconductor chip 611 that is relatively thin. Capacitances of the plurality of through silicon vias 631, 632 and 633 may be substantially the same as each other by forming the plurality of through silicon vias 631, 632 and 633 to have cross-sectional areas in inverse proportion to the thicknesses of the plurality of semiconductor chips 611, 612 and 613. That is, since the capacitance of each through silicon via 631, 632 and 633 is in proportion to a radius r and a height L of the through silicon via 631, 632 and 633 as described in Equation 1, the capacitance may be substantially fixed by decreasing the radius r as the height L increases. The bump 650 and the substrate 670 may be substantially the same as a bump 140 and a substrate 150 illustrated in FIG. 1, and thus detailed descriptions for the bump 650 and the substrate 670 are omitted.

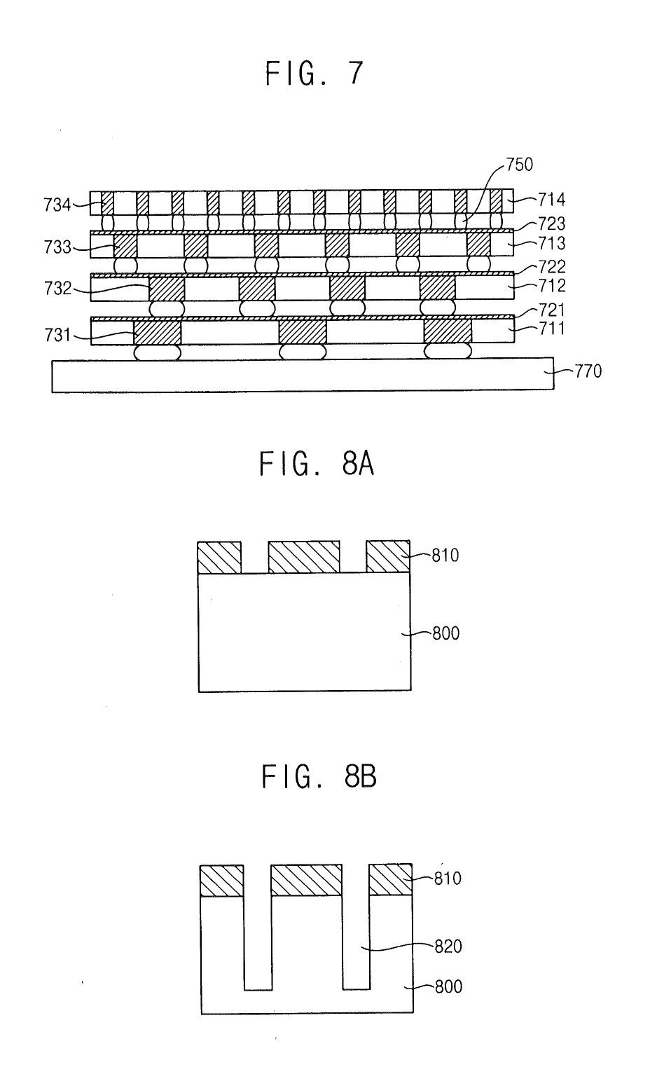

FIG. 7 is a cross-sectional view illustrating a chip stack package according to example embodiments. Components of the chip stack package, except a plurality of semiconductor chips 711, 712, 713 and 714, a plurality of wiring layers 721, 722 and 723, a plurality of through silicon vias 731, 732, 733 and 734, a plurality of bumps 750 and a substrate 770, are omitted in FIG. 7 for clarity of illustration.

Referring to FIG. 7, each semiconductor chip 711, 712 and 713 includes at least one through silicon via 731, 732 and 733. In some embodiments, the plurality of semiconductor chips 711, 712, 713 and 714 may be different types of semiconductor chips. For example, a first semiconductor chip 711 may be a central processing unit, and a second semiconductor chip 712 may be a memory device.

In some example embodiments, the number of through silicon vias 731, 732, 733 and 734 included in each semiconductor chip 711, 712, 713 and 714 may be determined according to each ball size of the semiconductor chip 711, 712, 713 and 714. For example, sizes of the bumps 750 formed beneath one semiconductor chip 711, 712, 713 and 714 may be the same as each other, and sizes of the bumps 750 formed beneath different semiconductor chips 711, 712, 713 and 714 may be different from each other. Cross-sectional areas of the through silicon vias 731, 732, 733 and 734 formed through one semiconductor chip 711, 712, 713 and 714 may be the same as each other, and cross-sectional areas of the through silicon vias 731, 732, 733 and 734 formed through different semiconductor chips 711, 712, 713 and 714 may be different from each other depending on the different sizes of the bumps 750. Further, the smaller a cross-sectional area of each through silicon via 731, 732, 733 and 734 included in one semiconductor chip 711, 712, 713 and 714 is, the more through silicon vias 731, 732, 733 and 734 the semiconductor chip 711, 712, 713 and 714 may include. In some example embodiments, the bumps 750 may be solder bumps.

In some example embodiments, a plurality of wiring layers 721, 722 and 723 may be formed to electrically connect the plurality of through silicon vias 731, 732, 733 and 734. For example, a first wiring layer 721 may be formed on a first semiconductor chip 711 to electrically connect a first through silicon via 731 to a second through silicon via 732, a second wiring layer 722 may be formed on a second semiconductor chip 712 to electrically connect a second through silicon via 732 to a third through silicon via 733, and a third wiring layer 723 may be formed on a third semiconductor chip 713 to electrically connect a third through silicon via 733 to a fourth through silicon via 734. In this case, the plurality of through silicon vias 731, 732, 733 and 734 may not be aligned in a line. The bump 750 and the substrate 770 may be substantially the same as a bump 140 and a substrate 150 illustrated in FIG. 1, and thus detailed descriptions for the bump 650 and the substrate 670 are omitted.

FIGS. 8A to 8E are cross-sectional views for describing a method of forming a through silicon via according to example embodiments. In FIGS. 8A to 8E, the method of forming through silicon vias in one semiconductor chip is illustrated.

Referring to FIG. 8A, a photo resist pattern 810 may be formed on a surface of a wafer 800 using a photo lithography process. For example, a photo resist layer may be formed on the wafer 800, and a mask pattern may be disposed on the photo resist layer. The photo resist pattern 810 may be formed on the wafer 800 by performing an exposing process and a developing process. In some example embodiments, semiconductor devices, such as a transistor, a capacitor, etc., may be further formed on the wafer 800.

Referring to FIG. 8B, a via hole 820 may be formed by etching the wafer 800 using the photo resist pattern 810 as an etching mask. In some example embodiments, the via hole 820 may be formed using a dry etching process, such as an inductively coupled plasma reactive ion etching (ICP-RIE) process.

Referring to FIG. 8C, an insulation layer 830 may be formed on an upper surface of the wafer 800 and a surface of the via hole 820. In some example embodiments, the insulation layer 830 may include silicon dioxide (SiO2), tetraethyl orthosilicate (TEOS), etc. According to example embodiments, the insulation layer 830 may be formed using a chemical vapor deposition (CVD) process, a plasma enhanced chemical vapor deposition (PECVD) process, a sputtering process, a spin coating process, a printing process, a high density plasma-chemical vapor deposition (HDP-CVD) process, a low pressure chemical vapor deposition (LPCVD) process, etc. The insulation layer 830 formed on the surface of the via hole 820 may be substantially the same as an insulating material 115 illustrated in FIG. 1.

Referring to FIG. 8D, a contact metal layer 840 may be formed on the insulation layer 830. The contact metal layer 840 may include a conductive material, such as tantalum (Ta), tantalum nitride (TaN), gold (Au), etc. The contact metal layer 840 may be coupled to a through silicon via 850 described below, and may serve as an input/output terminal for electrically connecting through silicon vias 850. In some example embodiments, the contact metal layer 840 may serve as a metal pad 125 illustrated in FIG. 1.

Referring to FIG. 8E, the through silicon via 850 may be formed by filling the via hole 820 with a conductive material. For example, the through silicon via 850 may be formed of copper (Cu), aluminum (Al), tin (Sn), nickel (Ni), gold (Au), tungsten (W), silicon (Si), polysilicon, or an alloy thereof. In some example embodiments, the through silicon via 850 and the contact metal layer 840 may be formed of the same material.

An exposed portion of the contact metal layer 840 and a protruding portion of the through silicon via 850 may be removed. In some example embodiments, an additional metal pad may be further formed on an upper surface of the through silicon via 850.

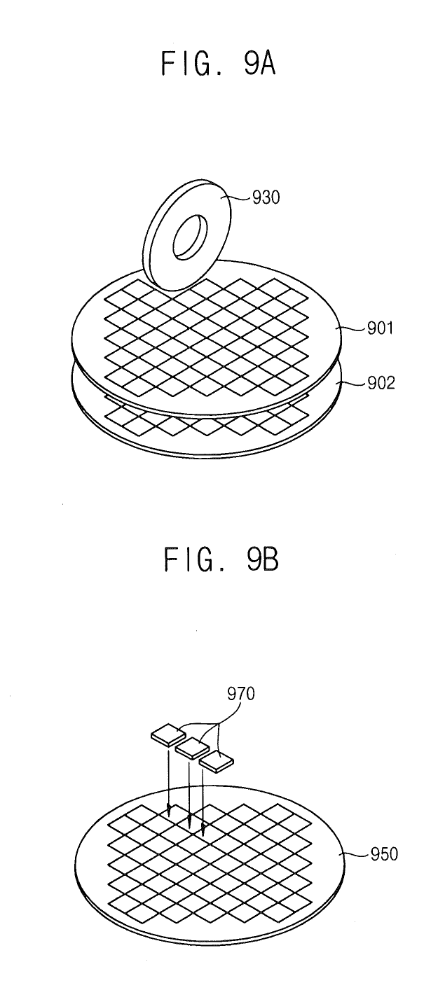

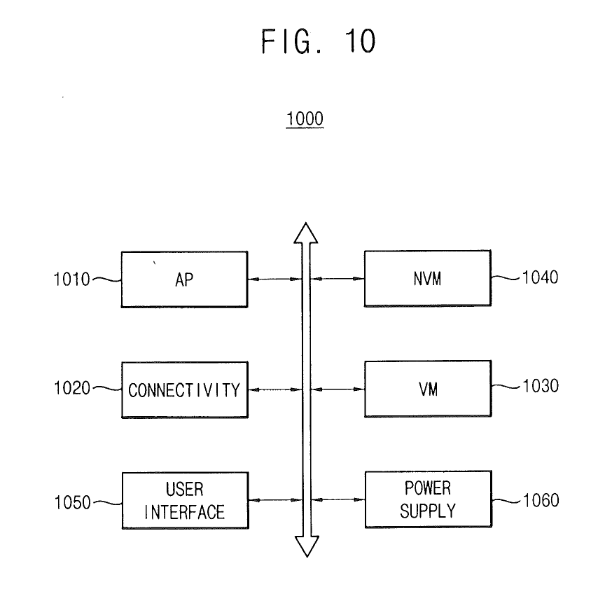

FIG. 9A is a diagram for describing an example of a wafer stack according to example embodiments. FIG. 9B is a diagram for describing an example of a die stack according to example embodiments.

Referring to FIG. 9A, a wafer stack may be formed by stacking wafers 901 and 902 including a plurality of dies. Each die may correspond to one semiconductor chip. The wafer stack may be divided into a plurality of chip stack packages by dicing the wafer stack using a blade 930.

Referring to FIG. 9B, die stacks may be formed by stacking a plurality of dies 970 on a wafer 950. Each die may correspond to one semiconductor chip. A chip stack package may be formed by stacking at least one die 970 on a die included in the wafer 950.

FIG. 10 is a block diagram illustrating a mobile system including a chip stack package according to example embodiments.

Referring to FIG. 10, a mobile system 1000 may include semiconductor chip types such as an application processor 1010, a connectivity unit 1020, a volatile memory device 1030, a nonvolatile memory device 1040, a user interface 1050 and a power supply 1060. Multiple chips of the aforementioned chip types may be stacked to form an integrated circuit chip group according to various embodiments described herein. According to example embodiments, the mobile system 1000 may be any mobile system, such as a mobile phone, a smart phone, a tablet computer, a laptop computer, a personal digital assistant (PDA), a portable multimedia player (PMP), a digital camera, a portable game console, a music player, a camcorder, a video player, a navigation system, etc.

The application processor 1010 may execute applications, such as an internet browser, a game application, a video player application, etc. The application processor 1010 may include any number of processor cores. For example, the application processor 1010 may be a single core processor or a multi-core processor, such as a dual-core processor, a quad-core processor, a hexa-core processor, etc. The application processor 1010 may be coupled to a cache memory inside or outside the application processor 1010.

The connectivity unit 1020 may communicate with an external device. For example, the connectivity unit 1020 may perform a USB communication, an Ethernet communication, a near field communication (NFC), a radio frequency identification (RFID) communication, a mobile telecommunication, a memory card communication, etc.

The volatile memory device 1030 may store an instruction/data processed by the application processor 1010, or may serve as a working memory. For example, the volatile memory device 1030 may be implemented by a dynamic random access memory (DRAM), a static random access memory (SRAM), a mobile DRAM, or the like. In some example embodiments, the volatile memory device 1030 may be stacked on the application processor 1010 to form a chip stack package. Further, through silicon vias may be formed through the application processor 1010 and the volatile memory device 1030 to electrically connect the application processor 1010 and the volatile memory device 1030. Accordingly, space efficiency of the mobile system 1000 may be improved.

The nonvolatile memory device 1040 may store a boot image for booting the mobile system 1000. For example, the nonvolatile memory device 1040 may be implemented by an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like. In some example embodiments, at least two of the application processor 1010, the volatile memory device 1030 and the nonvolatile memory device 1040 may be stacked to form a chip stack package.

The user interface 1050 may include at least one input device, such as a keypad, a touch screen, etc., and at least one output device, such as a display device, a speaker, etc. The power supply 1060 may supply the mobile system 1000 with power. In some example embodiments, the mobile system 1000 may further include a camera image processor (CIS), and a storage device, such as a memory card, a solid state drive (SSD), a hard disk drive (HDD), a CD-ROM, etc.

According to example embodiments, the mobile system 1000 and/or components of the mobile system 1000 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The inventive concept may be applied to any integrated circuit chips such as semiconductor chips. For example, the inventive concept may be applied to chips for a portable device, a DRAM module for a server computer, processor chips, memory chips, graphic chips, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An integrated circuit chip stack package comprising:
a first integrated circuit chip including a first through silicon via that extends through the first integrated circuit chip;
a second integrated circuit chip stacked on the first integrated circuit chip, the second integrated circuit chip including a second through silicon via that extends through the second integrated circuit chip, the second through silicon via being on the first through silicon via, and the second through silicon via having a cross-sectional area smaller than that of the first through silicon via; and
a third integrated circuit chip stacked on the second integrated circuit chip, the third integrated circuit chip including a third through silicon via that extends through the third integrated circuit chip, the third through silicon via being on the second through silicon via, and the third through silicon via having a cross-sectional area smaller than that of the second through silicon via.

2. The integrated circuit chip stack package of claim 1, wherein a capacitance of a signal path including the first, second, and third through silicon vias is a function of cross-sectional areas of the first, second and/or third through silicon vias.

3. The integrated circuit chip stack package of claim 1, wherein the first, second, and third through silicon vias are aligned such that a surface of the second through silicon via is adjacent a surface of the first through silicon via and a surface of the third through silicon via is adjacent a surface of the second through silicon via opposite the first through silicon via.

4. The integrated circuit chip stack package of claim 1, further comprising:
a first metal pad adjacent the first through silicon via;
a second metal pad adjacent the first through silicon via, opposite the first metal pad;
a third metal pad adjacent the second through silicon via;
a fourth metal pad adjacent the second through silicon via, opposite the third metal pad;
a fifth metal pad adjacent the third through silicon via;
a sixth metal pad adjacent the third through silicon via, opposite the fifth metal pad;
a first bump adjacent the first metal pad, opposite the first through silicon via;
a second bump adjacent the second metal pad and adjacent the third metal pad; and
a third bump adjacent the fourth metal pad and adjacent the fifth metal pad,
wherein the first integrated circuit chip is electrically coupled to the second integrated circuit chip through the second metal pad, the second bump and the third metal pad, and
wherein the second integrated circuit chip is electrically coupled to the third integrated circuit chip through the fourth metal pad, the third bump and the fifth metal pad.

5. The integrated circuit chip stack package of claim 4, wherein the first, second, and third through silicon vias, the first, second, third, fourth, fifth, and sixth metal pads and the first, second, and third bumps each comprises copper (Cu), aluminum (Al), tin (Sn), nickel (Ni), gold (Au), tungsten (W), silicon (Si) and/or polysilicon.

6. The integrated circuit chip stack package of claim 1, wherein the first integrated circuit chip further includes a fourth through silicon via formed through the first integrated circuit chip,
wherein the second integrated circuit chip further includes a fifth through silicon via that extends through the second integrated circuit chip,
wherein the third integrated circuit chip further includes a sixth through silicon via that extends through the third integrated circuit chip,
wherein the fourth through silicon via has a cross-sectional area same as that of the first through silicon via,
wherein the fifth through silicon via has a cross-sectional area same as that of the second through silicon via, and
wherein the sixth through silicon via has a cross-sectional area same as that of the third through silicon via.

7. An integrated circuit chip stack package, comprising:
a plurality of stacked integrated circuit chips, a respective one of which includes one or more through silicon vias extending through the respective integrated circuit chip,
wherein the plurality of integrated circuit chips are stacked such that the through silicon vias are aligned to form at least one signal path, and
wherein the plurality of through silicon vias have different cross-sectional areas.

8. The integrated circuit chip stack package of claim 7, wherein a capacitance of a signal path including the plurality of through silicon vias is a function of cross-sectional areas of the plurality of through silicon vias.

9. The integrated circuit chip stack package of claim 7, further comprising
a plurality of wiring layers, a respective one of which is on a respective one of the plurality of integrated circuit chips,
wherein the wiring layers electrically connect one or more of the plurality of through silicon vias.

10. The integrated circuit chip stack package of claim 7, wherein the plurality of integrated circuit chips are different types of integrated circuit chips performing different functions.

11. The integrated circuit chip stack package of claim 7, wherein the cross-sectional areas of the plurality of through silicon vias decrease in a direction from a lowermost one of the plurality of integrated circuit chips in the integrated circuit chip stack to an uppermost one of the plurality of integrated circuit chips in the integrated circuit chip stack.

12. The integrated circuit chip stack package of claim 7, wherein the cross-sectional areas of the plurality of through silicon vias increase in a direction from a lowermost one of the plurality of integrated circuit chips in the integrated circuit chip stack to an uppermost one of the plurality of integrated circuit chips in the integrated circuit chip stack.

13. The integrated circuit chip stack package of claim 7, wherein the cross-sectional areas of the plurality of through silicon vias decrease in a direction from a lowermost one of the plurality of semiconductor chips to an uppermost one of the plurality of integrated circuit chips, and
wherein a respective one of the plurality of stacked integrated circuit chips further includes a plurality of respective through silicon vias having cross-sectional areas that increase in the direction from the lowermost one of the plurality of integrated circuit chips to the uppermost one of the plurality of integrated circuit chips.

14. The integrated circuit chip stack package of claim 7, wherein the cross-sectional area of each through silicon via is in inverse proportion to a thickness of a corresponding one of the plurality of integrated circuit chips.

15. The integrated circuit chip stack package of claim 14, wherein capacitances of the plurality of through silicon vias are same as each other.

16. An integrated circuit chip stack package, comprising:
a plurality of integrated circuit chip groups, at least one of the integrated circuit chip groups comprising a plurality of integrated circuit chips of a same type,
wherein the integrated circuit chip groups are stacked upon one another and the integrated circuit chips in a respective integrated circuit chip group are adjacent one another,
wherein the stacked integrated circuit chips each includes at least one through silicon via extending through the integrated circuit chip,
wherein the integrated circuit chips of the at least one of the integrated circuit chip groups comprising a plurality of integrated circuit chips of a same type are stacked such that the plurality of through silicon vias are aligned to form at least one signal path.

17. The integrated circuit chip stack package of claim 16, further comprising
a plurality of wiring layers, a respective one of which is on a respective one of the plurality of integrated circuit chips,
wherein the wiring layers electrically connect one or more of the plurality of through silicon vias.

18. The integrated circuit chip stack package of claim 16,
wherein the plurality of through silicon vias of the at least one of the integrated circuit chip groups comprising a plurality of integrated circuit chips of a same type have cross-sectional areas less than cross-sectional areas of the plurality of through silicon vias of the other integrated circuit chip groups.

19. The integrated circuit chip stack package of claim 16,
wherein the cross-sectional areas of the plurality of the through silicon vias of the one or more integrated circuit chips within at least one integrated circuit chip group change in a direction from a lowermost integrated circuit chip of the plurality of integrated circuit chips in the integrated circuit chip stack to an uppermost integrated circuit chip of the plurality of integrated circuit chips.

20. The integrated circuit chip stack package of claim 16,
wherein the cross-sectional areas of the plurality of the through silicon vias of the integrated circuit chips change in a direction from a lowermost integrated circuit chip in the integrated circuit chip stack to an uppermost integrated circuit chip in the integrated circuit chip stack.
